(19) United States
(12) Patent Application Publication
(10) Pub. No.: US 2021/0327774 A1
(43) Pub. Date: Oct. 21, 2021

(54) DISPLAY PANEL AND DISPLAY DEVICE

(71) Applicant: Wuhan China Star Optoelectronics Semiconductor Display Technology Co., Ltd., Wuhan (CN)

(72) Inventors: Jiayao Yang, Wuhan (CN); Qipei Zhang, Wuhan (CN)

(21) Appl. No.: 16/961,102

(22) PCT Filed: May 22, 2020
(86) PCT No.: PCT/CN2020/091869

§ 371 Date: Jul. 9, 2020

(30) Foreign Application Priority Data
Apr. 16, 2020 (CN) 202010298138..X

(51) Int. Cl. H01L 21/66

(52) U.S. Cl. CPC H01L 22/34

(57) ABSTRACT

An embodiment of the present application provides a display panel having an effective display area and an non-effective display area, and a bonding circuit board and a test circuit board are provided on the non-effective display area, wherein the test circuit board is provided on the first surface between the effective display area and the bonding circuit board, the test circuit board is configured to test the display panel. By designing the test circuit board not to be shared with the bonding circuit board, the risk of bonding failure and abnormal reliability caused by the undesirable damage during a test process of the bonding circuit board is reduced.

### BACKGROUND OF INVENTION

### Field of Invention

The present application relates to a field of display technology, in particular to a display panel and a display device.

### Description of Prior Art

With continuous narrowing of a frame and continuous improvement of resolution of an organic light-emitting diode (OLED) display panel, failure and reliability problems caused by undesirable damage during a test process are becoming more and more serious.

### SUMMARY OF INVENTION

Embodiments of the present application provide a display panel and a display device, which can effectively avoid the problems of product failure and abnormal reliability caused by undesirable damage during a test process.

An embodiment of the present application provides a display panel, including an effective display area and a non-effective display area disposed around the effective display area, wherein the display panel includes a first surface, a second surface, and a first side and second side arranged opposite to each other; a bonding circuit board is provided on the first surface of the non-effective display area and at a side closed to the first side, and the bonding circuit board includes at least two bonding pads; and a test circuit board is provided on the first surface between the effective display area and the bonding circuit board, the test circuit board is configured to test the display panel, and the test circuit board includes at least two test pads.

In some embodiments, the test circuit board includes a first test circuit board and a second test circuit board, the first test circuit board includes oppositely disposed first and second ends, the second test circuit board includes oppositely disposed third and fourth ends, the first and third ends are flush with opposite ends of the bonding circuit board, and a circuit area is defined between the second and fourth ends.

In some embodiments, a degree of closeness of the test pads is less than a degree of closeness of the bonding pads, and a number of the test pads is less than a number of bonding pads.

In some embodiments, a degree of closeness of the bonding pads or a degree of closeness of the test pads ranges from 50 μm to 200 μm.

In some embodiments, opposite sides of the bonding circuit board perpendicular to the first side are provided with reserved test pads, and the reserved test pads are connected to the test pads by signal lines.

In some embodiments, signal lines of the bonding pads extend from either side of the test circuit board to a side of the test circuit board away from the first side.

In some embodiments, gaps are defined between the test pads, and signal lines of the bonding pads extend to a side of the test circuit board away from the first side via the gaps of the test pads.

In some embodiments, a bonding mark is provided on opposite sides of the bonding circuit board, and the bonding mark is configured to align the bonding circuit board with a bonding machine during bonding.

In some embodiments, the display panel further includes a sealant disposed on a side of the bonding circuit board and the test circuit board away from the first surface, wherein the sealant is configured to encapsulate the bonding circuit board and the test circuit board.

In some embodiments, conductive contacts are provided between the bonding pads and between the test pads.

An embodiment of the present application provides a display device, including a display panel, display panel including an effective display area and a non-effective display area disposed around the effective display area, wherein the display panel includes a first surface, a second surface, and a first side and second side arranged opposite to each other; a bonding circuit board is provided on the first surface of the non-effective display area and at a side closed to the first side, and the bonding circuit board includes at least two bonding pads; and a test circuit board is provided on the first surface between the effective display area and the bonding circuit board, the test circuit board is configured to test the display panel, and the test circuit board includes at least two test pads.

In some embodiments, the test circuit board includes a first test circuit board and a second test circuit board, the first test circuit board includes oppositely disposed first and second ends, the second test circuit board includes oppositely disposed third and fourth ends, the first and third ends are flush with opposite ends of the bonding circuit board, and a circuit area is defined between the second and fourth ends.

In some embodiments, a degree of closeness of the test pads is less than a degree of closeness of the bonding pads, and a number of the test pads is less than a number of bonding pads.

In some embodiments, a degree of closeness of the bonding pads or a degree of closeness of the test pads ranges from 50 μm to 200 μm.

In some embodiments, opposite sides of the bonding circuit board perpendicular to the first side are provided with reserved test pads, and the reserved test pads are connected to the test pads by signal lines.

In some embodiments, signal lines of the bonding pads extend from either side of the test circuit board to a side of the test circuit board away from the first side.

In some embodiments, gaps are defined between the test pads, and signal lines of the bonding pads extend to a side of the test circuit board away from the first side via the gaps of the test pads.

In some embodiments, the signal line of the bonding pads extends via either side of the test circuit board to the side of the test circuit board away from the first side.

In some embodiments, a bonding mark is provided on opposite sides of the bonding circuit board, and the bonding mark is configured to align the bonding circuit board with a bonding machine during bonding.

In some embodiments, the display panel further includes a sealant disposed on a side of the bonding circuit board and the test circuit board away from the first surface, wherein the sealant is configured to encapsulate the bonding circuit board and the test circuit board.

In some embodiments, conductive contacts are provided between the bonding pads and between the test pads.

### BRIEF DESCRIPTION OF DRAWINGS

In order to more clearly illustrate the embodiments or the technical solutions of the existing art, the drawings illustrating the embodiments or the existing art will be briefly described below. Obviously, the drawings in the following description merely illustrate some embodiments of the present invention. Other drawings may also be obtained by those skilled in the art according to these figures without paying creative work.

FIG. 1 is a schematic structural diagram of a first surface of a display panel provided by an embodiment of the present application.

FIG. 2 is a first partial schematic diagram of the first surface of a display panel provided by an embodiment of the present application.

FIG. 3 is a second partial schematic diagram of the first surface of the display panel provided by an embodiment of the present application.

FIG. 4 is a first connection manner of bonding pads and test pads provided by an embodiment of the present application.

FIG. 5 is a second connection manner of bonding pads and test pads provided by an embodiment of the present application.

FIG. 6 is a third partial schematic view of the first surface of the display panel provided by an embodiment of the present application.

FIG. 7 is a schematic structural diagram of a display panel provided by an embodiment of the present application.

FIG. 8 is a fourth partial schematic diagram of the first surface of the display panel provided by an embodiment of the present application.

FIG. 9 is a schematic structural diagram of a display device provided by an embodiment of the present application.

### DETAILED DESCRIPTION OF PREFERRED EMBODIMENTS

The technical solutions in the embodiments of the present application will be clearly and completely described in the following with reference to the accompanying drawings in the embodiments. It is apparent that the described embodiments are only a part of the embodiments of the present application, and not all of them. All other embodiments obtained by a person skilled in the art based on the embodiments of the present application without creative efforts are within the scope of the present application.

It should be noted that, in the description of the present application, it should be understood that the terms “upper”, “lower”, “front”, “back”, “left”, “right”, “inner”, “outer”, and the like are based on the orientation or positional relationship shown in the drawings, and is merely for the convenience of describing the present invention and simplifying the description, and does not indicate or imply that the indicated devices or components must to be in particular orientations, or constructed and operated in a particular orientation, and thus are not to be construed as limiting the invention.

An embodiment of the present application provides a display panel and a display device. The display panel will be described in detail below.

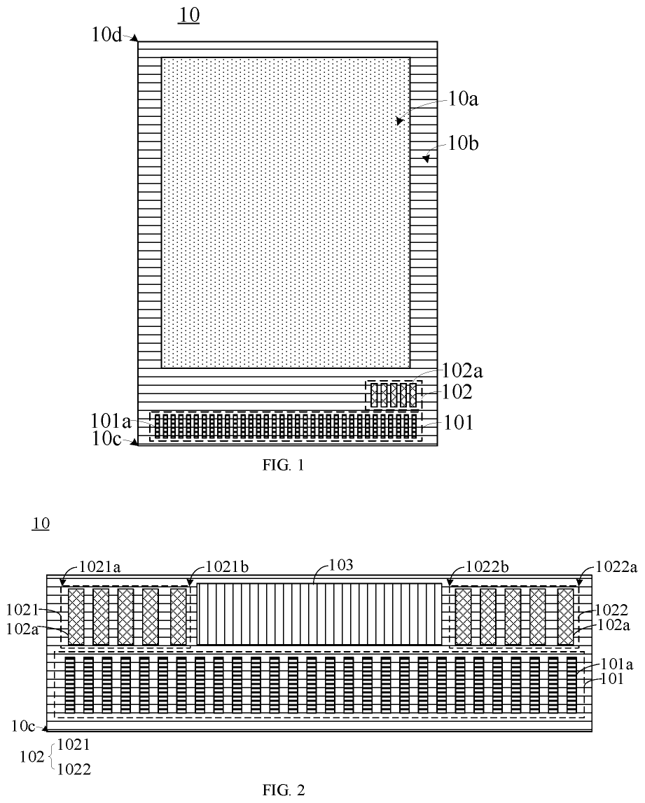

Referring to FIG. 1, FIG. 1 is a schematic structural diagram of a first surface of a display panel 10 provided by an embodiment of the present application. The display panel 10 includes an effective display area 10a and a non-effective display area 10b disposed around the effective display area 10a, wherein the display panel 10 includes a first surface, a second surface, and a first side 10c and second side 10d arranged opposite to each other; a bonding circuit board 101 is provided on the first surface of the non-effective display area 10b and at a side closed to the first side 10c, and the bonding circuit board 101 includes at least two bonding pads 101a; and a test circuit board 102 is provided on the first surface between the effective display area 10a and the bonding circuit board 101, the test circuit board 102 is configured to test the display panel 10, and the test circuit board 102 includes at least two test pads 102a. By designing the test circuit board 102 not to be shared with the bonding circuit board 101, the risk of bonding failure and abnormal reliability caused by the undesirable damage during a test process of the bonding circuit board is reduced. In addition, by designing the test circuit board 102 and the bonding circuit board 101 to be disposed in double rows, a horizontal spacing of the display panel 10 can also be saved.

A degree of closeness of the test pads 102a is less than a degree of closeness of the bonding pads 101a, and a number of the test pads 102a is less than a number of bonding pads 101a. The degree of closeness of the test pads 102a and the degree of closeness of the bonding pads 101a refer to a width of each of the pads plus a size of the spacing between the pads. Specifically, the degree of closeness of the bonding pads 101a or the degree of closeness of the test pads 102a provided by the present application is 50 μm to 200 μm. Further, the degree of closeness of the bonding pads 101a or the degree of closeness of the test pads 102a provided by the present application is 50 μm, 55 μm, 100 μm, 150 μm, 195 μm, or 200 μm. The test pads 102a are used for testing during the manufacturing process, and therefore, the degree of closeness of the test pads 102a is set to be smaller than that of the bonding pads 101a, and the number of test pads 102a is set to be smaller than the number of bonding pads 101a, such that the precision of the test pads 102a can be improved, and the production time and production cost invested in the test process during the manufacturing process, which is beneficial to improve the production efficiency of the display panel 10.

Referring to FIG. 2, FIG. 2 is a schematic diagram of a first partial structure of the first surface of the display panel 10 provided by an embodiment of the present application. The test circuit board 102 includes a first test circuit board 1021 and a second test circuit board 1022. The first test circuit board 1021 includes a first end 1021a and a second end 1021b disposed oppositely, and the second test circuit board 1022 includes a third end 1022a and the fourth end 1022b disposed oppositely. The first end 1021a and the third end 1022a are flush with opposite ends of the bonding circuit board 101, and a circuit area 103 is defined between the second end 1021b and the fourth end 1022b. The test circuit board 102 is divided into a first test circuit board 1021 and a second test circuit board 1022, to reserve the circuit area 103 for setting other circuit boards or other devices of the display panel 10. By arranging the first test circuit board 1021 and the second test circuit board 1022 at opposite ends, damage to the device or circuit board in the circuit area 103 can also be prevented during the test process, thereby preventing the device or circuit board in the circuit area 103 from being defective.

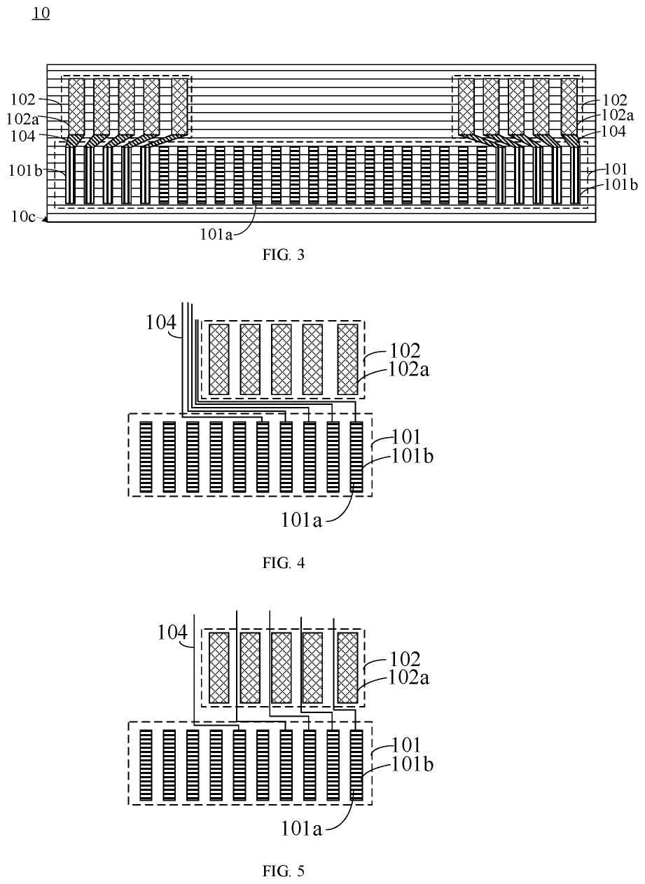

Referring to FIG. 3, which is a second partial schematic view of the first side of the display panel 10 provided by an embodiment of the present application. Opposite sides of the bonding circuit board 101 perpendicular to the first side 10c are provided with reserved test pads 101b, and the reserved test pads 101b are connected to the test pads 102a by signal lines 104. Specifically, one of the reserved test pads 101b and one of test pads 102a are respectively connected by a signal line 104. In the case that the lateral spacing of the display panel 10 is relatively large, the provision of reserved test pads 101b on opposite sides of the bonding circuit board 101 can make the test more accurate.

Referring to FIG. 4, FIG. 4 is a first connection manner of the bonding pads 101a and the test pads 102a provided by an embodiment of the present application. The signal lines 104 of the bonding pads 101a extend from either side of the test circuit board 102 to a side of the test circuit board 102 away from the first side 10c. In FIG. 4, the extension from the left side is taken as an example, and the arrangement of the signal lines 104 is also only for illustration, not for limitation of the present invention.

Referring to FIG. 5, FIG. 5 is a second connection manner of the bonding pads 101a and the test pads 102a provided by an embodiment of the present application. gaps 102b are defined between the test pads 102a, and signal lines 104 of the bonding pads 101a extend to a side of the test circuit board 102 away from the first side 10c via the gaps 102b of the test pads 102a. The arrangement of the signal linea 104 in the FIG. 5 is only for illustration, not for limitation of the present invention.

The connection manners of the bonding pads 101a and the test pads 102a provided in the embodiments of the present application can avoid damage or destruction of the signal lines 104 on the bonding pads 101a during the test process, and because the signal lines 104 is set to bypass the test pads, the signal lines 104 can be prevented from being damaged during the test, which may cause the defective bonding circuit board 101 and impact the subsequent process.

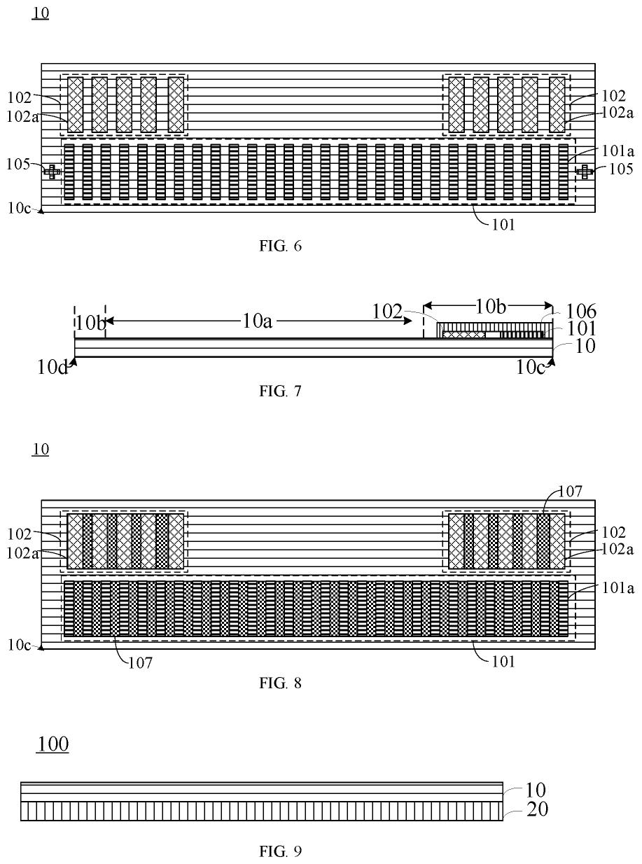

Referring to FIG. 6, FIG. 6 is a third partial schematic diagram of the first side of the display panel 10 provided by an embodiment of the present application. Bonding marks 105 are provided on opposite sides of the bonding circuit board 101, and the bonding marks 105 are used for aligning the bonding circuit board 101 with a bonding machine during bonding.

Referring to FIG. 7, FIG. 7 is a schematic structural diagram of a display panel 10 provided by an embodiment of the present application. The display panel 10 further includes a sealant 106 disposed on a side of the bonding circuit board 101 and the test circuit board 102 away from the first surface. The sealant 106 is configured to encapsulate the bonding circuit board 101 and the test circuit board 102.

Referring to FIG. 8, FIG. 8 is a fourth partial schematic diagram of the first side of the display panel 10 provided by the embodiment of the present application. Conductive contacts 107 are provided between the bonding pads 101a and the test pads 102a. Material of the conductive contacts 107 is gold, brass, or a combination thereof. The conductive contacts 107 are also called connecting fingers, and can be configured to transmit signals between pads, or to transmit signals between the bonding circuit board 101 and devices bonded with the bonding circuit board 101. The provision of the conductive contacts 107 can effectively increase the bonding package area and improve the package reliability.

An embodiment of the present application still provides a display device 100. FIG. 9 is a schematic structural diagram of the display device 100 provided by the embodiment of the present application. The display panel 100 includes the display panel 10 and a backlight module 20, and the display device 100 may further include other devices. The backlight module 20 and other devices and their assembly in the embodiments of the present application are related technologies well known to those skilled in the art, and will not be described in detail herein for brevity.

The display device 100 provided by an embodiment of the present application includes a display panel 10 and a backlight module 20. In the display panel 10, by designing the test circuit board used in the test process not to be shared with the bonding circuit board, the risk of bonding failure and abnormal reliability caused by the undesirable damage during the test process of the bonding circuit board is reduced. In addition, by designing the test circuit board and the bonding circuit board to be disposed in double rows, a horizontal spacing of the display panel 10 can also be saved.

The foregoing is a detailed description of a backlight module provided by the embodiments of the present disclosure. The principles and implementations of the present disclosure are described herein by using specific examples. The description of the above embodiments is only for helping to understand the method of the present disclosure, and the core concept. Also, those skilled in the art may make some changes in the specific implementation and application scope without departing from the concept of the present disclosure. In summary, the content of the present specification should not be construed as limiting the disclosure.

What is claimed is:

1. A display panel, comprising an effective display area and a non-effective display area disposed around the effective display area, wherein
the display panel comprises a first surface, a second surface, and a first side and second side arranged opposite to each other;
a bonding circuit board is provided on the first surface of the non-effective display area and at a side closed to the first side, and the bonding circuit board comprises at least two bonding pads; and
a test circuit board is provided on the first surface between the effective display area and the bonding circuit board, the test circuit board is configured to test the display panel, and the test circuit board comprises at least two test pads.

2. The display panel according to claim 1, wherein the test circuit board comprises a first test circuit board and a second test circuit board, the first test circuit board comprises oppositely disposed first and second ends, the second test circuit board comprises oppositely disposed third and fourth ends, the first and third ends are flush with opposite ends of the bonding circuit board, and a circuit area is defined between the second and fourth ends.

3. The display panel according to claim 1, wherein a degree of closeness of the test pads is less than a degree of closeness of the bonding pads, and a number of the test pads is less than a number of bonding pads.

4. The display panel according to claim 3, wherein a degree of closeness of the bonding pads or a degree of closeness of the test pads ranges from 50 μm to 200 μm.

5. The display panel according to claim 1, wherein opposite sides of the bonding circuit board perpendicular to the first side are provided with reserved test pads, and the reserved test pads are connected to the test pads by signal lines.

6. The display panel according to claim 1, wherein signal lines of the bonding pads extend from either side of the test circuit board to a side of the test circuit board away from the first side.

7. The display panel according to claim 1, wherein gaps are defined between the test pads, and signal lines of the bonding pads extend to a side of the test circuit board away from the first side via the gaps of the test pads.

8. The display panel according to claim 1, wherein a bonding mark is provided on opposite sides of the bonding circuit board, and the bonding mark is configured to align the bonding circuit board with a bonding machine during bonding.

9. The display panel according to claim 1, further comprising a sealant disposed on a side of the bonding circuit board and the test circuit board away from the first surface, wherein the sealant is configured to encapsulate the bonding circuit board and the test circuit board.

10. The display panel according to claim 1, wherein conductive contacts are provided between the bonding pads and between the test pads.

11. A display device, comprising a display panel, display panel comprising an effective display area and a non-effective display area disposed around the effective display area, wherein
the display panel comprises a first surface, a second surface, and a first side and second side arranged opposite to each other;
a bonding circuit board is provided on the first surface of the non-effective display area and at a side closed to the first side, and the bonding circuit board comprises at least two bonding pads; and
a test circuit board is provided on the first surface between the effective display area and the bonding circuit board, the test circuit board is configured to test the display panel, and the test circuit board comprises at least two test pads.

12. The display device according to claim 11, wherein the test circuit board comprises a first test circuit board and a second test circuit board, the first test circuit board comprises oppositely disposed first and second ends, the second test circuit board comprises oppositely disposed third and fourth ends, the first and third ends are flush with opposite ends of the bonding circuit board, and a circuit area is defined between the second and fourth ends.

13. The display device according to claim 11, wherein a degree of closeness of the test pads is less than a degree of closeness of the bonding pads, and a number of the test pads is less than a number of bonding pads.

14. The display panel according to claim 13, wherein a degree of closeness of the bonding pads or a degree of closeness of the test pads ranges from 50 μm to 200 μm.

15. The display device according to claim 11, wherein opposite sides of the bonding circuit board perpendicular to the first side are provided with reserved test pads, and the reserved test pads are connected to the test pads by signal lines.

16. The display device according to claim 11, wherein signal lines of the bonding pads extend from either side of the test circuit board to a side of the test circuit board away from the first side.

17. The display device according to claim 11, wherein gaps are defined between the test pads, and signal lines of the bonding pads extend to a side of the test circuit board away from the first side via the gaps of the test pads.

16. The display device according to claim 11, wherein the signal line of the bonding pads extends via either side of the test circuit board to the side of the test circuit board away from the first side.

18. The display device according to claim 11, wherein a bonding mark is provided on opposite sides of the bonding circuit board, and the bonding mark is configured to align the bonding circuit board with a bonding machine during bonding.

19. The display device according to claim 11, further comprising a sealant disposed on a side of the bonding circuit board and the test circuit board away from the first surface, wherein the sealant is configured to encapsulate the bonding circuit board and the test circuit board.

20. The display device according to claim 11, wherein conductive contacts are provided between the bonding pads and between the test pads.
